(19) United States
(12) Patent Application Publication
(10) Pub. No.: US 2018/0068886 A1
(43) Pub. Date: Mar. 8, 2018

(54) POROUS SEMICONDUCTOR LAYER TRANSFER FOR AN INTEGRATED CIRCUIT STRUCTURE

(71) Applicant: QUALCOMM Incorporated, San Diego, CA (US)

(72) Inventors: Richard HAMMOND, San Diego, CA (US); Sinan GOKTEPELI, San Diego, CA (US)

(21) Appl. No.: 15/256,341

(22) Filed: Sep. 2, 2016

(51) Int. Cl. H01L 21/762; H01L 21/84; H01L 23/66; H01L 27/12; H01Q 1/22

(52) U.S. Cl. CPC H01L 21/76259; H01L 21/84; H01L 2223/6677; H01L 27/1203; H01Q 1/2283; H01L 23/66

(57) ABSTRACT

An integrated radio frequency (RF) circuit structure may include an active device on a front-side surface of a semiconductor device layer. A backside surface opposite the front-side surface of the semiconductor device layer may be supported by a backside dielectric layer. The integrated RF circuit structure may also include a handle substrate on a front-side dielectric layer that is on a front-side of the active device and a least a portion of the front-side surface of the semiconductor device layer. The integrated RF circuit structure may further include the backside dielectric layer on the backside surface of the semiconductor device layer. The backside dielectric layer may be arranged distal from the front-side dielectric layer.

### TECHNICAL FIELD

The present disclosure generally relates to integrated circuits (ICs). More specifically, the present disclosure relates to a method and apparatus for porous semiconductor layer transfer for an integrated circuit structure.

### BACKGROUND

Mobile RF chip designs (e.g., mobile RF transceivers), including high performance diplexers, have migrated to a deep sub-micron process node due to cost and power consumption considerations. The design of such mobile RF transceivers becomes complex at this deep sub-micron process node. The design complexity of these mobile RF transceivers is further complicated by added circuit functions to support communication enhancements, such as carrier aggregation. Further design challenges for mobile RF transceivers include analog/RF performance considerations, including mismatch, noise and other performance considerations. The design of these mobile RF transceivers includes the use of additional passive devices, for example, to suppress resonance, and/or to perform filtering, bypassing and coupling.

Silicon on insulator (SOI) technology replaces conventional silicon substrates with a layered silicon-insulator-silicon substrate to reduce parasitic device capacitance and improve performance. SOI-based devices differ from conventional silicon-built devices because the silicon junction is above an electrical insulator, typically a buried oxide (BOX) layer. A reduced thickness BOX layer, however, may not sufficiently reduce the parasitic capacitance caused by the proximity of an active device on the silicon layer and a substrate supporting the BOX layer.

For example, high performance complementary metal oxide semiconductor (CMOS) radio frequency (RF) switch technologies are currently manufactured using SOI substrates. To increase device isolation and reduce RF losses, such switch devices may then be physically bonded to a high resistivity (HR) handle wafer, such as HR-silicon or sapphire. The increased spatial separation, due to numerous layers of insulating dielectric, of the switch device from the underlying substrate dramatically improves the RF performance of the CMOS switch. Unfortunately the use of SOI wafers is quite expensive relative to the cost of a bulk semiconductor wafer.

### SUMMARY

A method of fabricating an integrated circuit structure may include etching a bulk semiconductor wafer to create a porous semiconductor layer. The method may also include epitaxially growing a semiconductor device layer on the porous semiconductor layer. The method may further include fabricating an active device on the semiconductor device layer. The method may also include depositing a front-side dielectric on the active device. The method may further include bonding a handle substrate to the front-side dielectric on the active device. The method may also include removing at least a portion of the bulk semiconductor wafer. The method may further include selectively etching away the porous semiconductor layer, while retaining the semiconductor device layer.

An integrated radio frequency (RF) circuit structure may include an active device on a front-side surface of a semiconductor device layer. A backside surface opposite the front-side surface of the semiconductor device layer may be supported by a backside dielectric layer. The integrated RF circuit structure may also include a handle substrate on a front-side dielectric layer that is on a front-side of the active device and a least a portion of the front-side surface of the semiconductor device layer. The integrated RF circuit structure may further include the backside dielectric layer on the backside surface of the semiconductor device layer. The backside dielectric layer may be arranged distal from the front-side dielectric layer.

An integrated radio frequency (RF) circuit structure may include means for switching on a front-side surface of a semiconductor device layer. A backside surface opposite the front-side surface of the semiconductor device layer may be supported by a backside dielectric layer. The integrated RF circuit structure may also include a handle substrate on a front-side dielectric layer that is on a front-side of the switching means and a least a portion of the front-side surface of the semiconductor device layer. The integrated RF circuit structure may further include the backside dielectric layer on the backside surface of the semiconductor device layer. The backside dielectric layer may be arranged distal from the front-side dielectric layer.

A radio frequency (RF) front end module may have an integrated RF circuit structure including a switch transistor on a front-side surface of a semiconductor device layer. A backside surface opposite the front-side surface of the semiconductor device layer may be supported by a backside dielectric layer. The integrated RF circuit structure may also include a handle substrate on a front-side dielectric layer that is on a front-side of the switch transistor and a least a portion of the front-side surface of the semiconductor device layer. The integrated RF circuit structure may further include the backside dielectric layer on the backside surface of the semiconductor device layer. The backside dielectric layer may be arranged distal from the front-side dielectric layer. The RF front end module may include an antenna coupled to an output of the switch transistor.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1A is a schematic diagram of a radio frequency (RF) front end (RFFE) module employing a diplexer according to an aspect of the present disclosure.

FIG. 1B is a schematic diagram of a radio frequency (RF) front end (RFFE) module employing diplexers for a chipset to provide carrier aggregation according to aspects of the present disclosure.

FIG. 2A is a diagram of a diplexer design according to an aspect of the present disclosure.

FIG. 2B is a diagram of a radio frequency (RF) front end module according to an aspect of the present disclosure.

FIGS. 3A to 3E show cross-sectional views of an integrated circuit structure during a layer transfer process according to aspects of the present disclosure.

FIGS. 4A to 4F show cross-sectional views of an integrated circuit structure during a porous silicon layer transfer process according to aspects of the present disclosure.

FIG. 5 is a process flow diagram illustrating a method of constructing an integrated circuit structure using a porous silicon layer transfer process according to aspects of the present disclosure.

FIG. 6 is a block diagram showing an exemplary wireless communication system in which a configuration of the disclosure may be advantageously employed.

FIG. 7 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

It will be understood that the term “layer” includes film and is not to be construed as indicating a vertical or horizontal thickness unless otherwise stated. As described herein, the term “substrate” may refer to a substrate of a diced wafer or may refer to a substrate of a wafer that is not diced. Similarly, the terms chip and die may be used interchangeably unless such interchanging would tax credulity.

Mobile radio frequency (RF) chip designs (e.g., mobile RF transceivers) have migrated to a deep sub-micron process node due to cost and power consumption considerations. The design complexity of mobile RF transceivers is further complicated by added circuit functions to support communication enhancements, such as carrier aggregation. Further design challenges for mobile RF transceivers include analog/RF performance considerations, including mismatch, noise and other performance considerations. The design of these mobile RF transceivers includes the use of passive devices, for example, to suppress resonance, and/or to perform filtering, bypassing and coupling.

Successful fabrication of modern semiconductor chip products involves interplay between the materials and the processes employed. In particular, the formation of passive devices during semiconductor fabrication in back-end-of-line (BEOL) processes is an increasingly challenging part of the process flow. This is particularly true in terms of maintaining a small feature size.

Silicon on insulator (SOI) technology replaces conventional silicon substrates with a layered silicon-insulator-silicon substrate to reduce parasitic device capacitance and improve performance. SOI-based devices differ from conventional silicon-built devices because the silicon junction is above an electrical insulator, typically a buried oxide (BOX) layer. A reduced thickness BOX layer, however, may not sufficiently reduce the parasitic capacitance caused by the proximity of a device on the silicon layer and a substrate supporting the BOX layer.

For example, high performance complementary metal oxide semiconductor (CMOS) radio frequency (RF) switch technologies are currently manufactured using SOI substrates. To increase device isolation and reduce RF losses, such switch devices may then be physically bonded to a high resistivity (HR) handle wafer, such as HR-silicon or sapphire. The increased spatial separation, due to numerous layers of insulating dielectric, of the switch device from the underlying substrate dramatically improves the RF performance of the CMOS switch.

In order to create ohmic contacts to the device and switch circuitry it may be necessary to remove the original SOI substrate. This can be achieved using a physical grind to thin the silicon handle of the SOI substrate, followed by a selective chemical etch, such as tetramethylammonium hydroxide (TMAH), which selectively removes the SOI handle wafer to expose the buried oxide (BOX) of the original SOI. The RF switch circuitry may then be electrically contacted from above using standard lithographic techniques. While this technology enables very high RF performance, it comes at a cost—namely the destruction of an expensive SOI substrate.

Aspects of the present invention relate to the use of a porous silicon substrate as a replacement for the current silicon-on-insulator (SOI) substrate technology currently used in the manufacture of RF switch technologies. That is, aspects of the present disclosure employ an inexpensive porous silicon substrate to enable the formation of a semiconductor device layer without the use of an expensive SOI substrate. According this aspect of the present disclosure, an integrated radio frequency (RF) circuit structure includes an active device on a front-side surface of the semiconductor device layer. A backside surface opposite the front-side surface of the semiconductor device layer is supported by a backside dielectric layer. The integrated circuit structure also includes a handle substrate on a front-side dielectric layer. The front-side dielectric layer is on a front-side of the active device and a least a portion of the front-side surface of the semiconductor device layer. The integrated circuit structure further includes the backside dielectric layer on the backside surface of the semiconductor device layer. The backside dielectric is arranged distal from the front-side dielectric layer.

For wireless communication, passive devices are used to process signals in a carrier aggregation system. In carrier aggregation systems, signals are communicated with both high band and low band frequencies. In a chipset, a passive device (e.g., a diplexer) is usually inserted between an antenna and a tuner (or a radio frequency (RF) switch) to ensure high performance. Usually, a diplexer design includes inductors and capacitors. Diplexers can attain high performance by using inductors and capacitors that have a high quality (Q)-factor. High performance diplexers can also be attained by reducing the electromagnetic coupling between components, which may be achieved through an arrangement of the geometry and direction of the components.

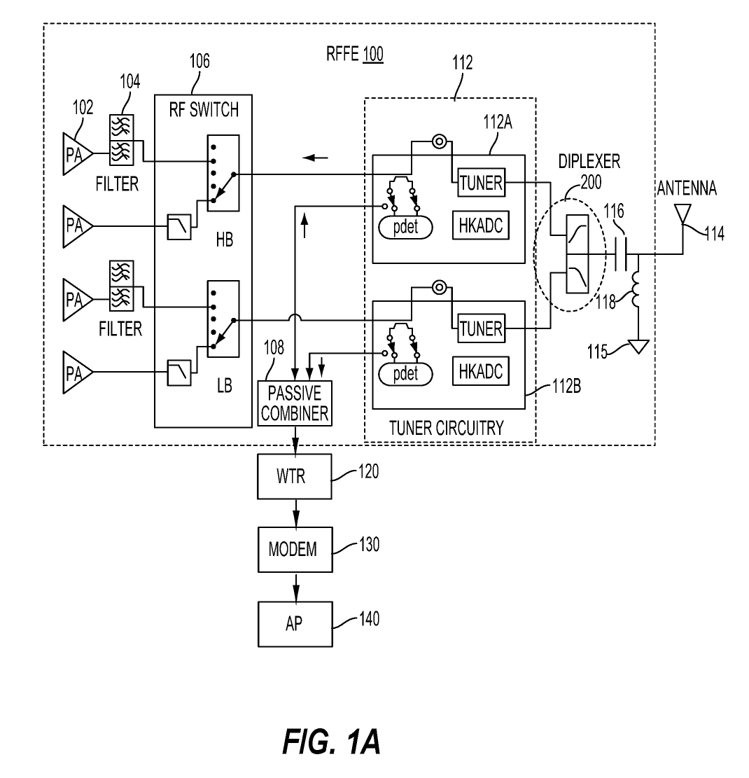

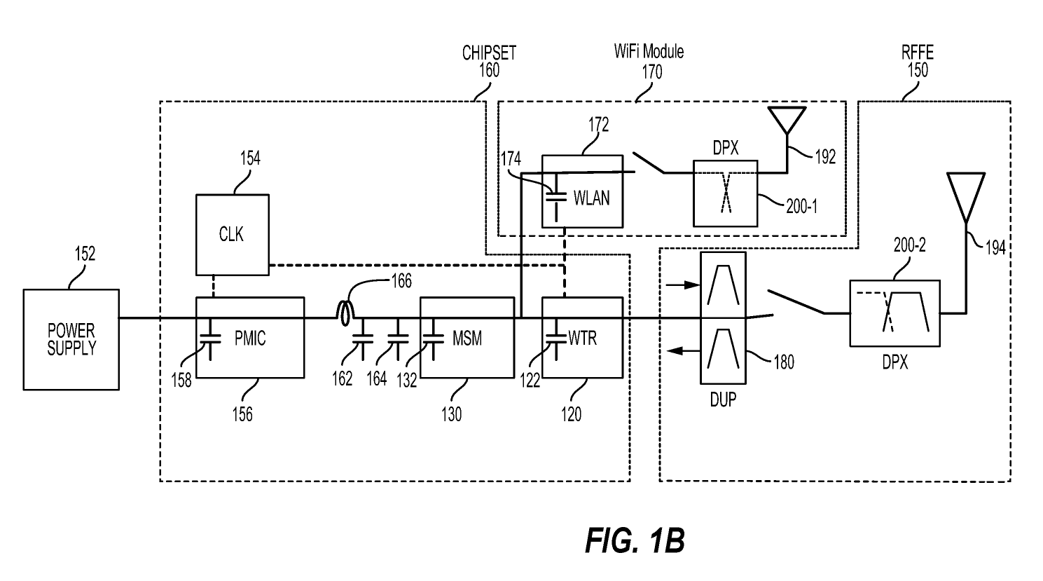

FIG. 1A is a schematic diagram of a radio frequency (RF) front end (RFFE) module 100 employing a diplexer 200 according to an aspect of the present disclosure. The RF front end module 100 includes power amplifiers 102, duplexer/filters 104, and a radio frequency (RF) switch module 106. The power amplifiers 102 amplify signal(s) to a certain power level for transmission. The duplexer/filters 104 filter the input/output signals according to a variety of different parameters, including frequency, insertion loss, rejection or other like parameters. In addition, the RF switch module 106 may select certain portions of the input signals to pass on to the rest of the RF front end module 100.

The RF front end module 100 also includes tuner circuitry 112 (e.g., first tuner circuitry 112A and second tuner circuitry 112B), the diplexer 200, a capacitor 116, an inductor 118, a ground terminal 115 and an antenna 114. The tuner circuitry 112 (e.g., the first tuner circuitry 112A and the second tuner circuitry 112B) includes components such as a tuner, a portable data entry terminal (PDET), and a house keeping analog to digital converter (HKADC). The tuner circuitry 112 may perform impedance tuning (e.g., a voltage standing wave ratio (VSWR) optimization) for the antenna 114. The RF front end module 100 also includes a passive combiner 108 coupled to a wireless transceiver (WTR) 120. The passive combiner 108 combines the detected power from the first tuner circuitry 112A and the second tuner circuitry 112B. The wireless transceiver 120 processes the information from the passive combiner 108 and provides this information to a modem 130 (e.g., a mobile station modem (MSM)). The modem 130 provides a digital signal to an application processor (AP) 140.

As shown in FIG. 1A, the diplexer 200 is between the tuner component of the tuner circuitry 112 and the capacitor 116, the inductor 118, and the antenna 114. The diplexer 200 may be placed between the antenna 114 and the tuner circuitry 112 to provide high system performance from the RF front end module 100 to a chipset including the wireless transceiver 120, the modem 130 and the application processor 140. The diplexer 200 also performs frequency domain multiplexing on both high band frequencies and low band frequencies. After the diplexer 200 performs its frequency multiplexing functions on the input signals, the output of the diplexer 200 is fed to an optional LC (inductor/capacitor) network including the capacitor 116 and the inductor 118. The LC network may provide extra impedance matching components for the antenna 114, when desired. Then a signal with the particular frequency is transmitted or received by the antenna 114. Although a single capacitor and inductor are shown, multiple components are also contemplated.

FIG. 1B is a schematic diagram of a wireless local area network (WLAN) (e.g., WiFi) module 170 including a first diplexer 200-1 and an RF front end module 150 including a second diplexer 200-2 for a chipset 160 to provide carrier aggregation according to an aspect of the present disclosure. The WiFi module 170 includes the first diplexer 200-1 communicably coupling an antenna 192 to a wireless local area network module (e.g., WLAN module 172). The RF front end module 150 includes the second diplexer 200-2 communicably coupling an antenna 194 to the wireless transceiver (WTR) 120 through a duplexer 180. The wireless transceiver 120 and the WLAN module 172 of the WiFi module 170 are coupled to a modem (MSM, e.g., baseband modem) 130 that is powered by a power supply 152 through a power management integrated circuit (PMIC) 156. The chipset 160 also includes capacitors 162 and 164, as well as an inductor(s) 166 to provide signal integrity. The PMIC 156, the modem 130, the wireless transceiver 120, and the WLAN module 172 each include capacitors (e.g., 158, 132, 122, and 174) and operate according to a clock 154. The geometry and arrangement of the various inductor and capacitor components in the chipset 160 may reduce the electromagnetic coupling between the components.

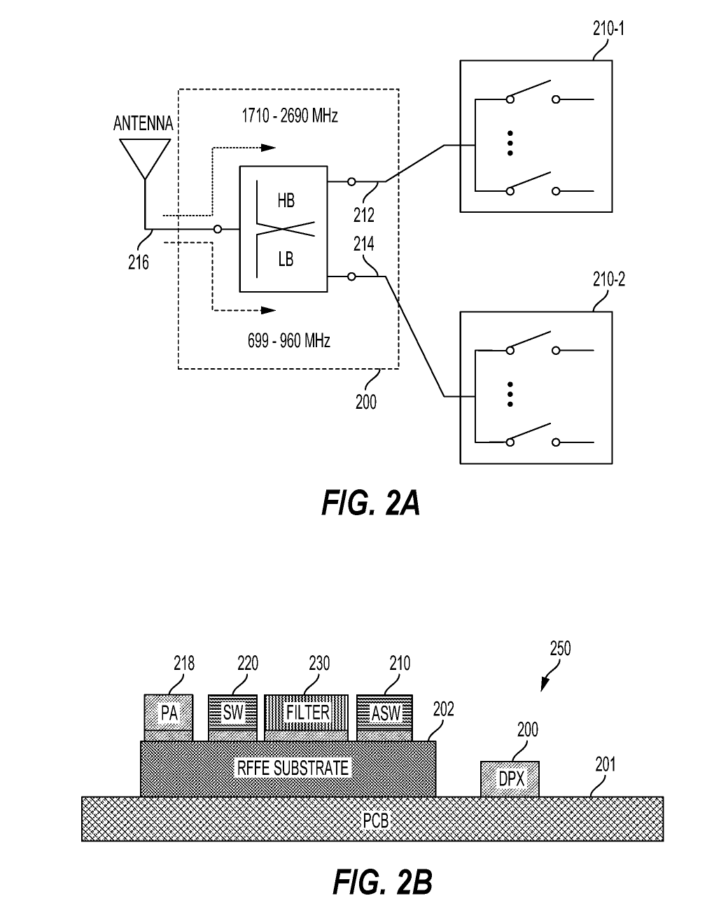

FIG. 2A is a diagram of a diplexer 200 according to an aspect of the present disclosure. The diplexer 200 includes a high band (HB) input port 212, a low band (LB) input port 214, and an antenna 216. A high band path of the diplexer 200 includes a high band antenna switch 210-1. A low band path of the diplexer 200 includes a low band antenna switch 210-2. A wireless device including an RF front end module may use the antenna switches 210 and the diplexer 200 to enable a wide range band for an RF input and an RF output of the wireless device. In addition, the antenna 216 may be a multiple input, multiple output (MIMO) antenna. Multiple input, multiple output antennas will be widely used for the RF front end of wireless devices to support features such as carrier aggregation.

FIG. 2B is a diagram of an RF front end module 250 according to an aspect of the present disclosure. The RF front end module 250 includes the antenna switch (ASW) 210 and diplexer 200 (or triplexer) to enable the wide range band noted in FIG. 2A. In addition, the RF front end module 250 includes filters 230, an RF switch 220 and power amplifiers 218 supported by a substrate 202. The filters 230 may include various LC filters, having inductors (L) and capacitors (C) arranged along the substrate 202 for forming a diplexer, a triplexer, low pass filters, balun filters, and/or notch filters to prevent high order harmonics in the RF front end module 250. The diplexer 200 may be implemented as a surface mount device (SMD) on a system board 201 (e.g., printed circuit board (PCB) or package substrate). Alternatively, the diplexer 200 may be implemented on the substrate 202.

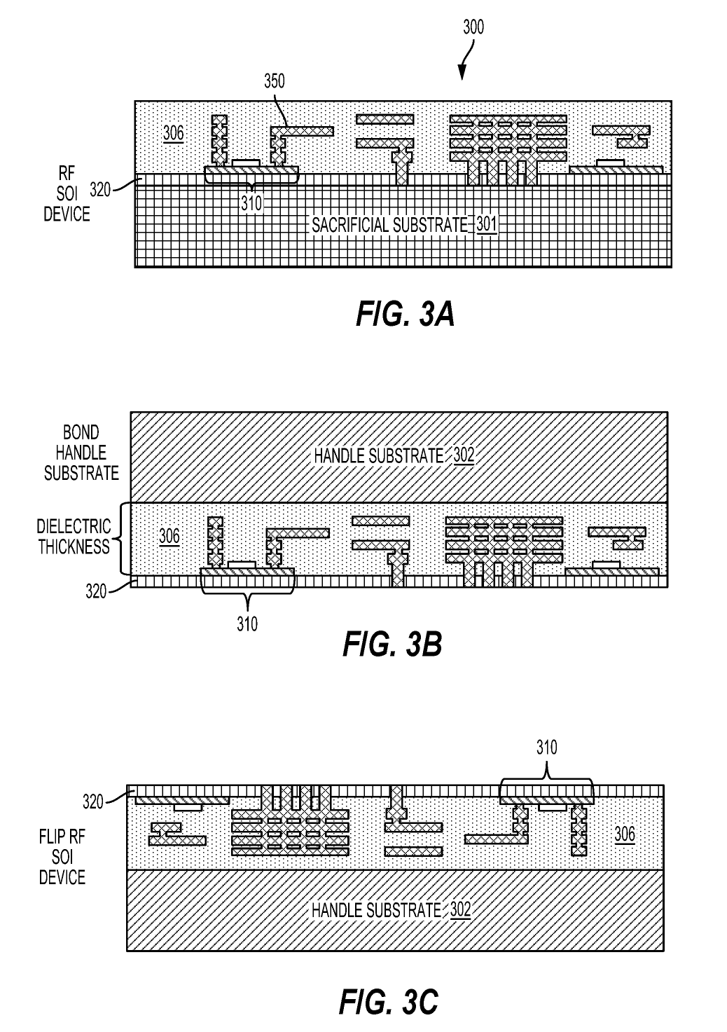

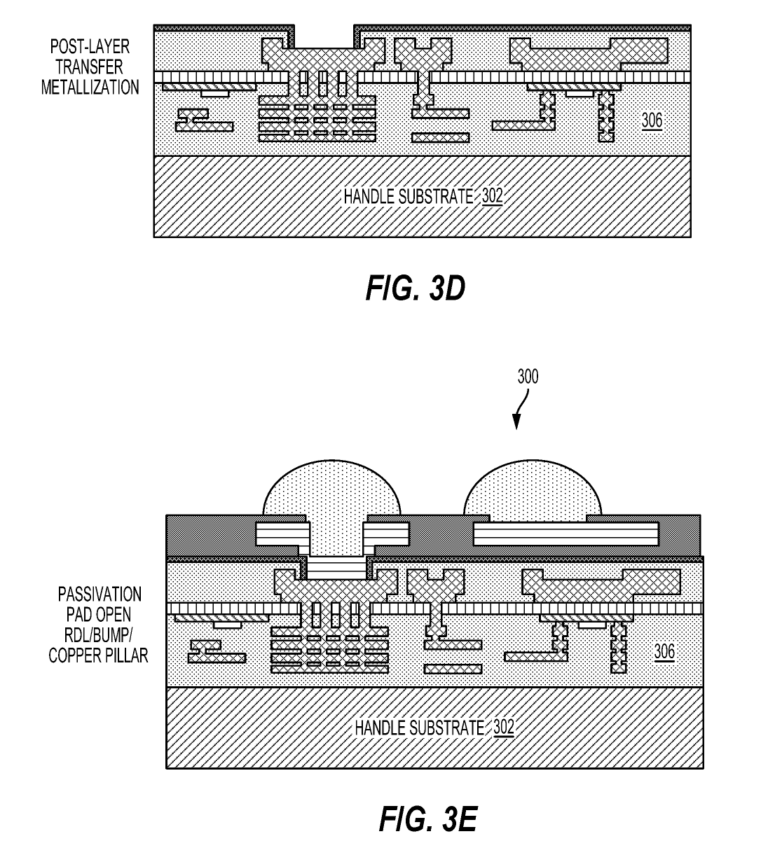

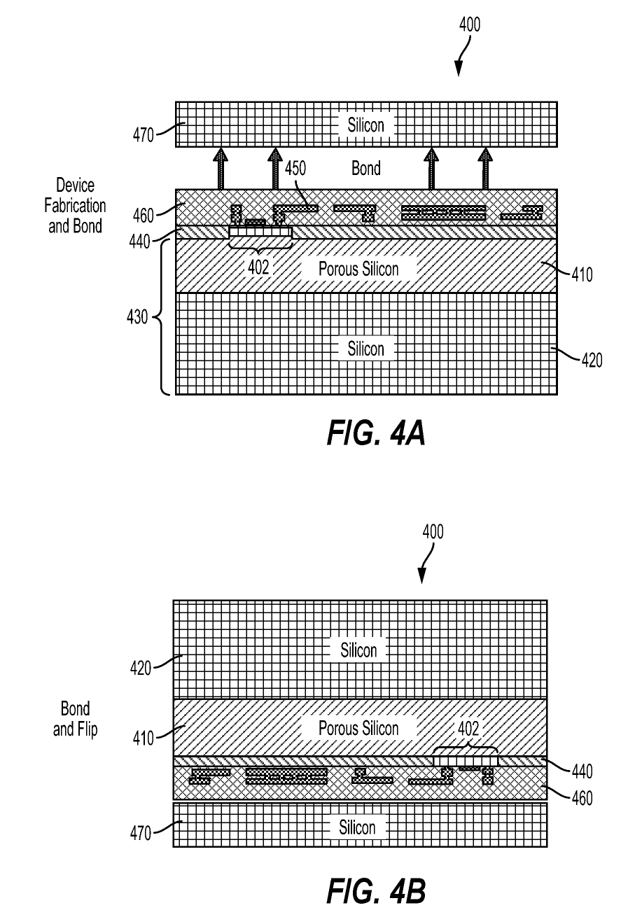

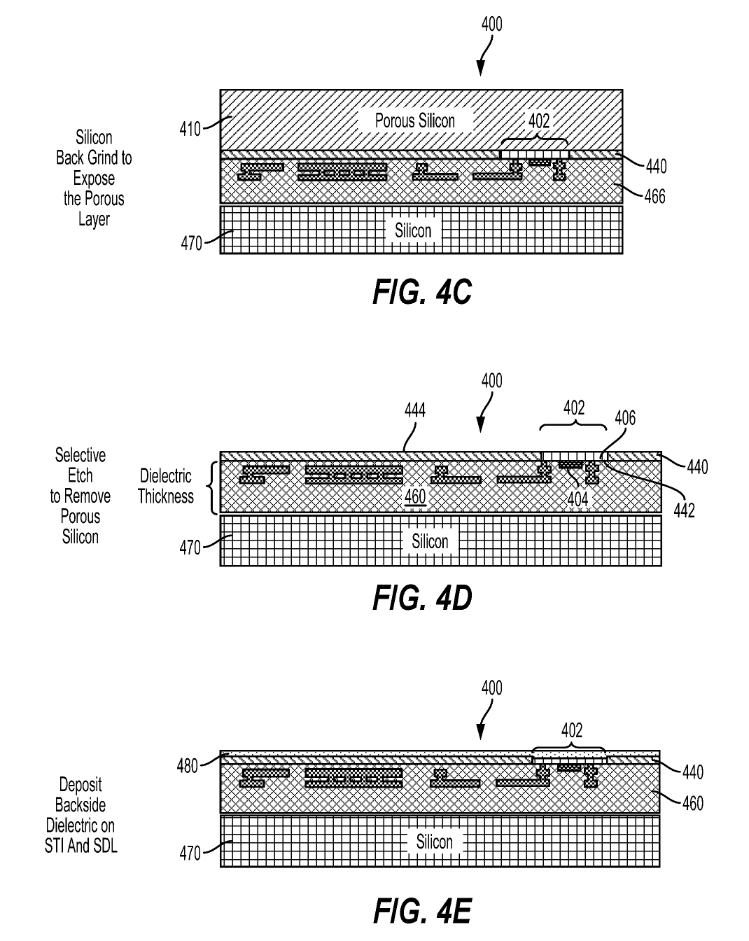

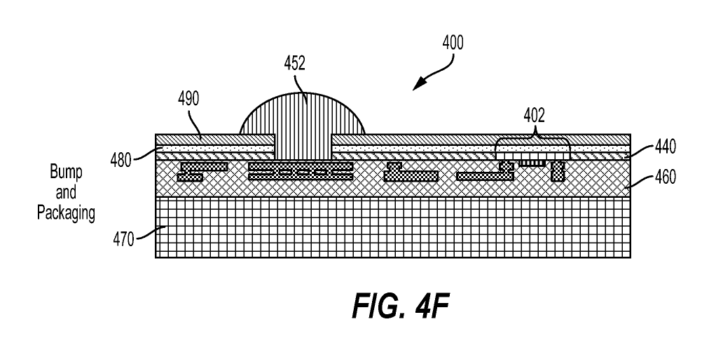

The RF front end module 250 may be implemented using silicon on insulator (SOI) technology that includes a layer transfer process. While this technology enables very high RF performance, it comes at a cost—namely the destruction of an expensive SOI substrate. As a result, aspects of the present disclosure include a layer transfer process to form a porous silicon layer, as shown in FIGS. 3A-3E and 4A-F.

FIGS. 3A to 3E show cross-sectional views of an integrated circuit structure 300 during a layer transfer process according to aspects of the present disclosure. As shown in FIG. 3A, an RF silicon on insulator (SOI) device includes a device 310 on a buried oxide (BOX) layer 320 supported by a sacrificial substrate 301 (e.g., a bulk wafer). The RF SOI device also includes interconnects 350 coupled to the device 310 within a first dielectric layer 306. As shown in FIG. 3B, a handle substrate 302 is bonded to the first dielectric layer 306 of the RF SOI device. In addition, the sacrificial substrate 301 is removed. Removal of the sacrificial substrate 301 using the layer transfer process enables high-performance, low-parasitic RF devices by increasing the dielectric thickness. That is, a parasitic capacitance of the RF SOI device is proportional to the dielectric thickness, which determines the distance between the device 310 and the handle substrate 302.

As shown in FIG. 3C, the RF SOI device is flipped once the handle substrate 302 is secured and the sacrificial substrate 301 is removed. As shown in FIG. 3D, a post layer transfer metallization process is performed using, for example, a regular complementary metal oxide semiconductor (CMOS) process. As shown in FIG. 3E, an integrated circuit structure 300 is completed by depositing a passivation layer, opening bond pads, depositing a redistribution layer (RDL), and forming conductive bumps/pillars to enable bonding of the integrated circuit structure 300 to a system board (e.g., a printed circuit board (PCB)).

Various aspects of the disclosure provide techniques for layer transfer and post transfer metallization to provide access to a backside of devices of an integrated circuit structure. By contrast, access to devices, formed during a front-end-of-line (FEOL) process, is conventionally provided during middle-end-of-line (MEOL) processing that provides contacts between the gates and source/drain regions of the devices and back-end-of-line (BEOL) interconnect layers (e.g., M1, M2, etc.).

Additional aspects of the present disclosure relate to the use of a porous silicon substrate as a replacement for the current silicon-on-insulator (SOI) substrate technology used in the manufacture of RF switch technologies with the proprietary layer transfer technology as illustrated in FIGS. 3A-3E. That is, aspects of the present disclosure employ an inexpensive porous silicon substrate to replace expensive SOI substrates.

Porous silicon is a form of the chemical element silicon that has introduced nanoporous holes in its microstructure, rendering a large surface to volume ratio in the order of, for example, 500 m²/cm³. Porous silicon may be created via the electrochemical etching of a single crystal silicon substrate in diluted hydrofluoric acid (HF). The porosity and the thickness of the porous silicon layer may be controlled by varying the current density, HF concentration, and duration of the electrochemical etch. Due to the large increase in surface area resulting from the electrochemical etch, porous silicon exhibits a significantly higher etch rate compared to single crystal silicon.

In the present disclosure, it is proposed that a relatively inexpensive silicon substrate undergoes electrochemical etching in order to create a porous silicon surface layer. Such porous layers are stable at high temperatures and the surface may be sealed via a high temperature anneal, including, but not limited to, at a temperature of approximately 1100° C. Once sealed, the silicon surface may then be used as a nucleation layer and a single crystal silicon re-growth layer may then be deposited with conventional epitaxial growth techniques.

It is proposed that this single crystal silicon re-growth layer be exchanged for the active device body layer of the SOI substrate and the porous silicon layer is utilized as the selective etch material.

In this manner, the porous substrate, including the silicon re-growth layer, will provide a direct replacement for the expensive SOI substrate. The porous substrate, including the silicon re-growth layer, will undergo CMOS processing and then is bonded to a high resistivity handle wafer. The original silicon substrate (from which the porous layer was created) will undergo a physical grind to expose the porous silicon layer. The exposed porous silicon layer will then undergo selective chemical etch removal, thereby leaving only the single crystal silicon re-growth layer remaining.

FIGS. 4A to 4F show cross-sectional views of an integrated circuit structure 400 during a porous silicon layer transfer process according to aspects of the present disclosure. Representatively, the integrated circuit structure 400 includes an active device 402 fabricated on a semiconductor device layer 440 (e.g., a silicon on insulator (SOI) layer) that is supported by a sacrificial substrate 430 (e.g., an SOI bulk wafer). The active device 402 may be a transistor or other like active logic. In RF applications, the active device 402 may be a switch transistor. In one aspect of the present disclosure, the semiconductor device layer 440 can be a single crystal silicon re-growth layer.

The sacrificial substrate 430 can have a porous layer 410 (e.g., a porous silicon layer) supported by a bulk wafer 420 (e.g., a bulk semiconductor wafer). For example, the porous layer 410 may be from under 10 microns to in excess of 100 microns thick, and may have a porosity of 20% to 70%. It is understood that these ranges are for illustrative purposes only, and other values are also acceptable. The semiconductor device layer 440 can be supported by the porous layer 410. The integrated circuit structure 400 can also include front-side metallization 450 coupled to the active device 402 within a front-side dielectric layer 460. The front-side dielectric layer 460 may cover the front-side metallization 450, and may be planarized subsequent to CMOS processing.

In one aspect of the present disclosure, the sacrificial substrate 430 can have a first porous layer (e.g., porous layer 410) and a second porous layer (not shown). The second porous layer may be adjacent to, or spaced apart from the first porous layer. The first porous layer and the second porous layer may have the same, similar, or different porosity and/or thickness. In related aspects of the present disclosure, the second porous layer can be thin with high porosity, in which a porosity of the second porous layer can be greater than a porosity of the first porous layer. The second porous layer can be supported by the first porous layer. The semiconductor device layer 440 can be supported by the second porous layer.

In another aspect of the present disclosure, etching the bulk semiconductor wafer can include etching the bulk semiconductor to create a third porous semiconductor layer, in which a porosity of the third porous layer is less than the porosity of the second porous layer, and similar to the porosity of the first porous layer. The third porous layer can be supported by the second porous layer. The semiconductor device layer 440 can be supported by the third porous layer.

As shown in FIGS. 4A and 4B, a handle substrate 470 (e.g., silicon) is bonded to the front-side dielectric layer 460 of the integrated circuit structure 400, and the integrated circuit structure 400 is flipped to expose the sacrificial substrate 430. In FIG. 4C, a silicon back grind removes the bulk wafer 420 and exposes the porous layer 410. Removal of the bulk wafer 420 using the layer transfer process enables high-performance, low-parasitic RF devices by increasing the dielectric thickness. That is, a parasitic capacitance of the integrated circuit structure 400 is proportional to the dielectric thickness, which determines the distance between the active device 402 and the handle substrate 470.

According to aspects of the present disclosure, the handle substrate 470 may be composed of a semiconductor material, such as silicon. In addition, an RF enhancement layer may be deposited on the front-side dielectric layer 460 on the active device 402. In this configuration, the handle substrate 470 is arranged on the RF enhancement layer, which may be a trap-rich layer. In this aspect of the present disclosure, the handle substrate 470 may be a processed wafer, including at least one other active device. Alternatively, the handle substrate 470 may be a passive substrate to further improve harmonics by reducing parasitic capacitance. In this configuration, the handle substrate 470 may include at least one passive device. As described herein, the term “passive substrate” may refer to a substrate of a diced wafer or panel, or may refer to the substrate of a wafer/panel that is not diced. In one configuration, the passive substrate is comprised of glass, air, quartz, sapphire, high-resistivity silicon, or other like passive material. The passive substrate may also be a coreless substrate.

In FIG. 4D, a selective etch is applied to remove the porous layer 410. For example, a chemical etch, such as a diluted tetramethylammonium hydroxide (TMAH) etch can be used. Because of the increased surface area of the porous layer 410, exceptionally highly selective etch rates, of the order of 100,000:1, for example, are achieved using industry standard wet etches. Additionally, unlike epitaxial P++ etch stops, using the porous layer 410 as an etch stop is intrinsic, and threshold voltage shifts due to dopants are reduced or even eliminated.

In one aspect of the present disclosure, the porous layer 410 can have an etch stop layer (not shown) for controlling the progression of the etch and preventing the etch from etching the semiconductor device layer 440. The etch stop layer can be adjacent to or spaced apart from the semiconductor device layer 440.

In another aspect of the present disclosure, removing at least a portion of the bulk semiconductor wafer can comprise cleaving the bulk semiconductor wafer at a second layer and reusing a remaining portion of the bulk semiconductor wafer. For example, the etch stop layer may be a cleave plane with a porosity higher than the porous layer 410 that allows the sacrificial substrate 430 to be cleaved from the semiconductor device layer 440. The remaining portion of the bulk semiconductor wafer can then be reused to perform another porous silicon layer process, or for other purposes.

As shown in FIG. 4E, a backside dielectric layer 480 is deposited on the shallow trench isolation (STI) region and the stack deposition layer (SDL). As shown in FIG. 4F, the integrated circuit structure 400 is completed by depositing a passivation layer 490, opening bond pads, depositing a redistribution layer (RDL), and forming of the conductive bumps/pillars 452 to enable bonding of the integrated circuit structure 400 to a system board (e.g., a printed circuit board (PCB)).

As shown in FIG. 4A to 4F, the integrated circuit structure 400 include middle-end-of-line (MEOL)/back-end-of-line (BEOL) interconnects coupled to the source/drain regions of the active device 402. As described herein, the MEOL/BEOL layers are referred to as front-side layers. By contrast, the layers supporting the active device 402 may be referred to as backside layers. According to this nomenclature, the front-side metallization 450 is coupled to the source/drain regions of the active device 402 and arranged in a front-side dielectric layer 460. In addition, the handle substrate 470 is coupled to the front-side dielectric layer 460. In this configuration, the backside dielectric layer 480 is adjacent to and directly supports the active device 402.

Referring again to FIGS. 4A to 4C, the use of the porous layer 410 enables the formation of the semiconductor device layer 440 without the use of an expensive SOI substrate. According this aspect of the present disclosure, the integrated circuit structure 400 includes the active device 402 on a front-side surface 442 of the semiconductor device layer 440. A backside surface 444 opposite the front-side surface 442 of the semiconductor device layer 440 is supported by a backside dielectric layer 480. The integrated circuit structure 400 also includes a handle substrate 470 on a front-side dielectric layer 460. The front-side dielectric layer 460 is on a front-side 404 of the active device 402 and a least a portion of the front-side surface 442 of the semiconductor device layer 440. The integrated circuit structure 400 further includes the backside dielectric layer 480 on the backside surface 444 of the semiconductor device layer 440. The backside dielectric layer 480 is arranged distal from the front-side dielectric layer 460.

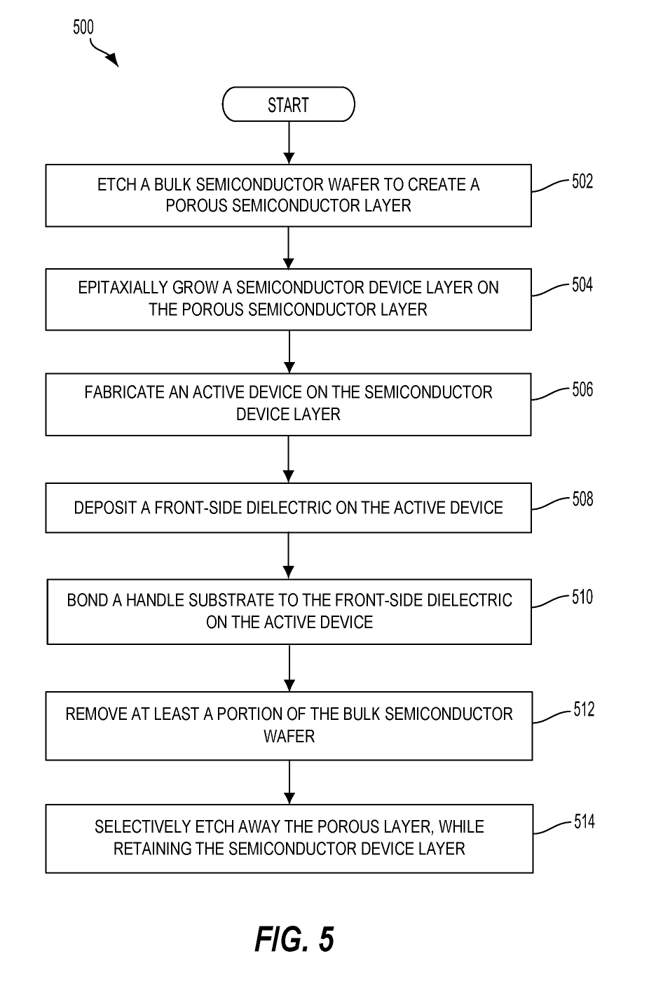

FIG. 5 is a process flow diagram illustrating a method 500 of fabricating an integrated circuit structure according to an aspect of the present disclosure. The method 500 begins in block 502, in which a bulk semiconductor wafer is etched to create a porous semiconductor layer. For example, as shown in FIG. 4A, a sacrificial substrate 430 (e.g., an SOI bulk wafer) is etched to create a porous layer 410 (e.g., a porous semiconductor layer) supported by a bulk wafer 420 (e.g., a bulk semiconductor wafer). The sacrificial substrate 430 can be silicon, such that the porous layer 410 is porous silicon and the bulk wafer 420 is silicon. In the configuration shown in FIG. 4A, the porous layer 410 is formed adjacent to the bulk wafer 420.

In one aspect of the present disclosure, the porous layer 410 may be from under 10 microns to in excess of 100 microns thick, and may be from 20% to 70% porous. It is understood that these ranges are for illustrative purposes only, and other values are also acceptable.

In another aspect of the present disclosure, etching the bulk semiconductor wafer can include etching the bulk semiconductor wafer to create a first porous semiconductor layer, and etching the bulk semiconductor wafer to create a second porous semiconductor layer. For example, the sacrificial substrate 430 can have a first porous layer (e.g., porous layer 410) and a second porous layer (not shown). The second porous layer may be adjacent to, or spaced apart from the first porous layer. The first porous layer and the second porous layer may have the same, similar, or different porosity and/or thickness. In related aspects of the present disclosure, the second porous layer can be thin with high porosity, in which a porosity of the second porous layer is greater than a porosity of the first porous layer. The second porous layer can be supported by the first porous layer. The semiconductor device layer 440 can be supported by the second porous layer.

In another aspect of the present disclosure, etching the bulk semiconductor wafer can include etching the bulk semiconductor to create a third porous semiconductor layer, in which a porosity of the third porous layer is less than the porosity of the second porous layer, and similar to the porosity of the first porous layer. The third porous layer can be supported by the second porous layer. The semiconductor device layer 440 can be supported by the third porous layer.

In block 504, a semiconductor device layer is epitaxially grown on the porous semiconductor layer. For example, as shown in FIG. 4A, the porous layer 410 is first sealed at a high temperature, and then the bulk wafer 420 (e.g., a silicon on insulator (SOI) layer) is epitaxially grown on the porous layer 410. The thickness and uniformity of the semiconductor device layer 440 is determined by the epitaxial growth process. The semiconductor device layer 440 may be composed of an epitaxially grown silicon layer.

In block 506, an active device is fabricated on the semiconductor device layer. For example, as shown in FIG. 4A, the active device 402 is fabricated according to known complementary metal oxide semiconductor (CMOS) processes on the semiconductor device layer 440.

In block 508, a front-side dielectric is deposited on the active device. For example, as shown in FIG. 4A, the front-side dielectric layer 460 is deposited on the active device 402. In one aspect of the present disclosure, the front-side dielectric layer 460 may cover the front-side metallization 450, and may be planarized subsequent to CMOS processing.

In block 510, a handle substrate is bonded to the front-side dielectric on the active device. As shown in FIGS. 4A-4B, the porous silicon layer transfer process includes bonding the handle substrate 470 (e.g., silicon) to the front-side dielectric layer 460.

In block 512, at least a portion the bulk semiconductor wafer is removed. For example, as shown in FIG. 4C, the bulk wafer 420 of the sacrificial substrate 430 is removed by silicon back grinding. The removal of the bulk wafer 420 exposes the porous layer 410.

In block 514, the porous layer is selectively etched away, while retaining the semiconductor device layer. As shown in FIGS. 4C and 4D, a selective etch is applied to remove the porous layer 410 while retaining the semiconductor device layer 440. For example, a chemical etch, such as a diluted tetramethylammonium hydroxide (TMAH) etch can be used. Because of the increased surface area of the porous layer 410, exceptionally highly selective etch rates, of the order of 100,000:1, for example, are achieved using industry standard wet etches.

In one aspect of the present disclosure, the porous layer can have an etch stop layer (not shown) for controlling the progression of the etch and preventing the etch from etching the semiconductor device layer 440. The etch stop layer can be adjacent to or spaced apart from the semiconductor device layer 440.

In another aspect of the present disclosure, removing at least a portion of the bulk semiconductor wafer can comprise cleaving the bulk semiconductor wafer at a second layer and reusing a remaining portion of the bulk semiconductor wafer. For example, the etch stop layer may be a cleave plane with a porosity higher than the porous layer 410 that allows the sacrificial substrate 430 to be cleaved from the semiconductor device layer 440. The remaining portion of the bulk semiconductor wafer can then be reused.

In another aspect of the present disclosure, the thickness and uniformity of the semiconductor device layer 440 is determined by the epitaxial growth process. Additionally, the semiconductor device layer 440 may have a surface roughness as determined by the epitaxial growth process

In additional aspects of the present disclosure, as shown in FIGS. 4E-4F, the backside dielectric layer 480 is deposited on the shallow trench isolation (STI) region and the stack deposition layer (SDL). The integrated circuit structure 400 is completed by depositing a passivation layer 490, opening bond pads, depositing a redistribution layer (RDL), and forming of the conductive bumps/pillars 452 to enable bonding of the integrated circuit structure 400 to a system board (e.g., a printed circuit board (PCB)). The conductive bumps/pillars 452 may also be coupled to backside metallization (not shown).

Removal of the sacrificial substrate 430 using the layer transfer process enables high-performance, low-parasitic devices by increasing the dielectric thickness. That is, a parasitic capacitance of the integrated circuit structure 400 is proportional to the dielectric thickness, which determines the distance between the active device 402 and the handle substrate 470.

According to a further aspect of the present disclosure, integrated RF circuitry structures, using a porous silicon layer transfer process, are described. The integrated RF circuit structure includes means for means for switching on a front-side surface of a semiconductor device layer. A backside surface opposite the front-side surface of the semiconductor device layer may be supported by a backside dielectric layer. The integrated RF circuit structure may also include a handle substrate on a front-side dielectric layer that is on a front-side of the switching means and a least a portion of the front-side surface of the semiconductor device layer. The switching means may be active device 402, shown in FIGS. 4A-4F. In another aspect, the aforementioned means may be any module or any apparatus configured to perform the functions recited by the aforementioned means.

An integrated radio frequency (RF) circuit structure may include means for switching on a front-side surface of a semiconductor device layer. A backside surface opposite the front-side surface of the semiconductor device layer may be supported by a backside dielectric layer. The integrated RF circuit structure may also include a handle substrate on a front-side dielectric layer that is on a front-side of the switching means and a least a portion of the front-side surface of the semiconductor device layer. The integrated RF circuit structure may further include the backside dielectric layer on the backside surface of the semiconductor device layer. The backside dielectric layer may be arranged distal from the front-side dielectric layer.

Porous silicon is a form of the chemical element silicon that has introduced nanoporous holes in its microstructure, rendering a large surface to volume ratio in the order of 500 m²/cm³. Porous silicon may be created via electrochemical etching of a single crystal silicon substrate in diluted hydrofluoric acid (HF). The porosity and the thickness of the porous silicon layer may be controlled by varying the current density, HF concentration, and duration of the electrochemical etch. Due to the large increase in surface area resulting from the electrochemical etch, porous silicon exhibits a significantly higher etch rate compared to single crystal silicon.

In the present disclosure, it is proposed that a relatively inexpensive silicon substrate undergoes electrochemical etching in order to create a porous silicon surface layer. Such porous layers are stable at high temperatures and the surface may be sealed via a high temperature anneal, such as including, but not limited to, at a temperature of approximately 1100° C. Once sealed, the silicon surface may then be used as a nucleation layer and a single crystal silicon layer may then be deposited using conventional epitaxial growth techniques.

It is proposed that this single crystal silicon re-growth layer be exchanged for the active device body layer of the SOI substrate and the porous silicon layer is utilized as the selective etch material.

In this manner, the porous substrate, including the silicon re-growth layer, provides a direct replacement for the expensive SOI substrate. The porous substrate, including the silicon re-growth layer, will undergo CMOS processing and then is bonded to a high resistivity handle wafer. The original silicon substrate (from which the porous layer 410 was created) undergoes a physical grind in order to expose the porous silicon layer. The exposed porous silicon layer will then undergo selective chemical etch removal, leaving only the single crystal silicon re-growth layer remaining.

Aspects of the present invention relate to the use of a porous silicon substrate as a replacement for the current silicon-on-insulator (SOI) substrate technology used in the manufacture of RF switch technologies. That is, aspects of the present disclosure employ an inexpensive porous silicon substrate to enable the formation of a semiconductor device layer without the use of an expensive SOI substrate. According to this aspect of the present disclosure, an integrated circuit structure includes an active device on a front-side surface of the semiconductor device layer. A backside surface opposite the front-side surface of the semiconductor device layer is supported by a backside dielectric layer. The integrated circuit structure also includes a handle substrate on a front-side dielectric layer. The front-side dielectric layer is on a front-side of the active device and a least a portion of the front-side surface of the semiconductor device layer. The integrated circuit structure further includes the backside dielectric layer on the backside surface of the semiconductor device layer. The backside dielectric is arranged distal from the front-side dielectric layer.

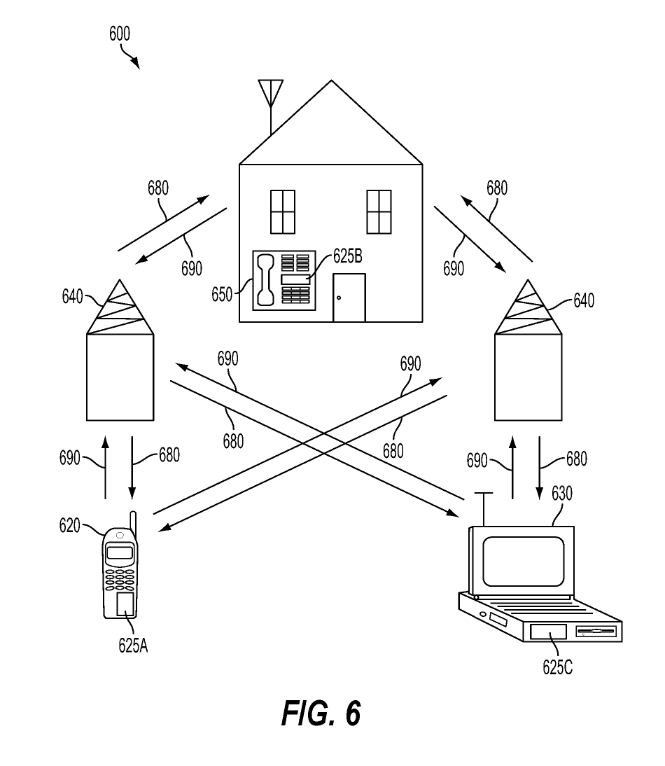

FIG. 6 is a block diagram showing an exemplary wireless communication system 600 in which an aspect of the disclosure may be advantageously employed. For purposes of illustration, FIG. 6 shows three remote units 620, 630, and 650 and two base stations 640. It will be recognized that wireless communication systems may have many more remote units and base stations. Remote units 620, 630, and 650 include IC devices 625A, 625C, and 625B that are fabricated using the porous silicon layer transfer process. It will be recognized that other devices may also be fabricated using the disclosed porous silicon layer transfer process, such as the base stations, switching devices, and network equipment. FIG. 6 shows forward link signals 680 from the base station 640 to the remote units 620, 630, and 650 and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 6 illustrates remote units according to the aspects of the disclosure, the disclosure is not limited to these exemplary illustrated units. Aspects of the disclosure may be suitably employed in many devices, which may be fabricated using the porous silicon layer transfer process.

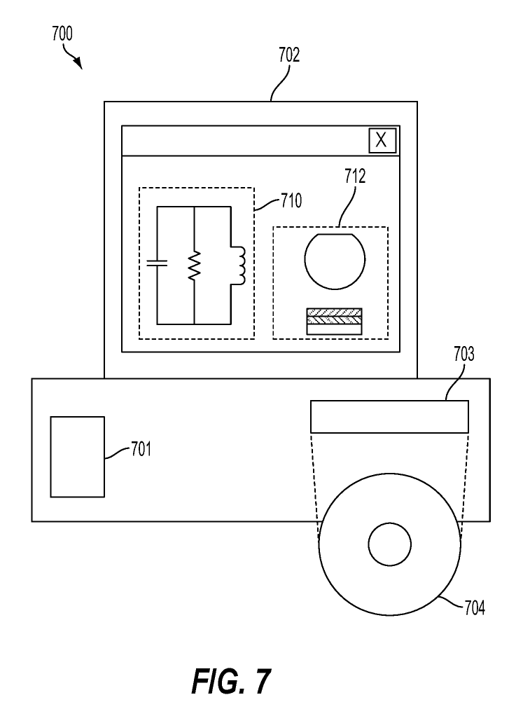

FIG. 7 is a block diagram illustrating a design workstation used for circuit, layout, and logic design of a semiconductor component, fabricated using the porous silicon layer transfer process disclosed above. A design workstation 700 includes a hard disk 701 containing operating system software, support files, and design software such as Cadence or OrCAD. The design workstation 700 also includes a display 702 to facilitate design of a circuit 710 or a semiconductor component 712 that is fabricated using the porous silicon layer transfer process. A storage medium 704 is provided for tangibly storing the circuit design 710 or the semiconductor component 712. The circuit design 710 or the semiconductor component 712 may be stored on the storage medium 704 in a file format such as GDSII or GERBER. The storage medium 704 may be a CD-ROM, DVD, hard disk, flash memory, or other appropriate device. Furthermore, the design workstation 700 includes a drive apparatus 703 for accepting input from or writing output to the storage medium 704.

Data recorded on the storage medium 704 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 704 facilitates the design of the circuit design 710 or the semiconductor component 712 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A method of fabricating an integrated circuit structure, comprising:
etching a bulk semiconductor wafer to create a porous semiconductor layer;
epitaxially growing a semiconductor device layer on the porous semiconductor layer;
fabricating an active device on the semiconductor device layer;
depositing a front-side dielectric on the active device;
bonding a handle substrate to the front-side dielectric on the active device;
removing at least a portion of the bulk semiconductor wafer; and
selectively etching away the porous semiconductor layer, while retaining the semiconductor device layer.

2. The method of claim 1, in which the porous semiconductor layer comprises an etch stop layer.

3. The method of claim 1, in which a porosity of the porous semiconductor layer is in a range of 20% to 70%.

4. The method of claim 1, in which the porous semiconductor layer comprises a cleave plane.

5. The method of claim 1, in which etching the bulk semiconductor wafer comprises:
etching the bulk semiconductor wafer to create a first porous semiconductor layer; and
etching the bulk semiconductor wafer to create a second porous semiconductor layer, having a porosity that is greater than the porosity of the first porous semiconductor layer.

6. The method of claim 5, in which removing at least the portion of the bulk semiconductor wafer comprises:
cleaving the bulk semiconductor wafer at the second porous semiconductor layer; and
reusing the remaining portion of the bulk semiconductor wafer.

7. The method of claim 5, in which the porosity of the first porous semiconductor layer is 20%.

8. The method of claim 5, in which the porosity of the second porous semiconductor layer is 70%.

9. The method of claim 5, in which etching the bulk semiconductor wafer comprises etching the bulk semiconductor wafer to create a third porous semiconductor layer, in which the porosity of the third porous semiconductor layer is less than the porosity of the second porous semiconductor layer.

10. The method of claim 9, in which the porosity of the third porous semiconductor layer is 20%.

11. The method of claim 1, further comprising integrating the integrated circuit structure into an RF front end module, the RF front end module incorporated into at least one of a music player, a video player, an entertainment unit, a navigation device, a communications device, a personal digital assistant (PDA), a fixed location data unit, a mobile phone, and a portable computer.

12. An integrated radio frequency (RF) circuit structure, comprising:
an active device on a front-side surface of a semiconductor device layer, in which a backside surface opposite the front-side surface of the semiconductor device layer is supported by a backside dielectric layer;
a handle substrate on a front-side dielectric layer that is on a front-side of the active device and a least a portion of the front-side surface of the semiconductor device layer; and
the backside dielectric layer on the backside surface of the semiconductor device layer, the backside dielectric layer being arranged distal from the front-side dielectric layer.

13. The integrated RF circuit structure of claim 12, in which the semiconductor device layer comprises an epitaxially grown silicon layer.

14. The integrated RF circuit structure of claim 13, in which a thickness of the epitaxially grown silicon layer is in a range of 150 to 750 angstroms.

15. The integrated RF circuit structure of claim 12, further comprising:
an RF enhancement layer on the front-side dielectric layer on the active device; and
the handle substrate is arranged on the RF enhancement layer.

16. The integrated RF circuit structure of claim 12, further comprising a passivation layer directly on the backside-dielectric layer, the passivation layer arranged distal from the handle substrate.

17. The integrated RF circuit structure of claim 12, integrated into an RF front end module, the RF front end module incorporated into at least one of a music player, a video player, an entertainment unit, a navigation device, a communications device, a personal digital assistant (PDA), a fixed location data unit, a mobile phone, and a portable computer.

18. An integrated radio frequency (RF) circuit structure, comprising:
means for switching on a front-side surface of a semiconductor device layer, in which a backside surface opposite the front-side surface of the semiconductor device layer is supported by a backside dielectric layer;
a handle substrate on a front-side dielectric layer that is on a front-side of the switching means and a least a portion of the front-side surface of the semiconductor device layer; and
the backside dielectric layer on the backside surface of the semiconductor device layer, the backside dielectric layer being arranged distal from the front-side dielectric layer.

19. The integrated RF circuit structure of claim 18, in which the semiconductor device layer comprises an epitaxially grown silicon layer.

20. The integrated RF circuit structure of claim 19, in which a thickness of the epitaxially grown silicon layer is in a range of 150 to 750 angstroms.

21. The integrated RF circuit structure of claim 18, integrated into an RF front end module, the RF front end module incorporated into at least one of a music player, a video player, an entertainment unit, a navigation device, a communications device, a personal digital assistant (PDA), a fixed location data unit, a mobile phone, and a portable computer.

22. A radio frequency (RF) front end module, comprising:
an integrated RF circuit structure comprising a switch transistor on a front-side surface of a semiconductor device layer, in which a backside surface opposite the front-side surface of the semiconductor device layer is supported by a backside dielectric layer, a handle substrate on a front-side dielectric layer that is on a front-side of the switch transistor and a least a portion of the front-side surface of the semiconductor device layer, and the backside dielectric layer on the backside surface of the semiconductor device layer, the backside dielectric layer being arranged distal from the front-side dielectric layer; and
an antenna coupled to an output of the switch transistor.

23. The RF front end module of claim 22, in which the semiconductor device layer comprises an epitaxially grown silicon layer.

24. The RF front end module of claim 22, incorporated into at least one of a music player, a video player, an entertainment unit, a navigation device, a communications device, a personal digital assistant (PDA), a fixed location data unit, a mobile phone, and a portable computer.
